(19) United States
(12) Patent Application Publication
(10) Pub. No.: US 2009/0053126 A1
(43) Pub. Date: Feb. 26, 2009

(54) METHOD FOR MASS PRODUCTION OF NANOSTRUCTURES USING MESOPOROUS TEMPLATES AND NANOSTRUCTURES PRODUCED BY THE SAME

(75) Inventors: Eun Kyung LEE, Suwon-si (KR); Byoung Lyong CHOI, Seoul (KR); Dong Mock HWANG, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/931,991

(22) Filed: Oct. 31, 2007

(30) Foreign Application Priority Data
Mar. 15, 2007 (KR) 10-2007-0025524

(51) Int. Cl. H01L 21/20; C01B 33/023

(52) U.S. Cl. 423/350; 438/478; 257/E21.09; 977/762; 977/891

(57) ABSTRACT

A method for the mass production of nanostructures is provided. The method comprises introducing metal catalyst nanoparticles into a plurality of uniformly sized pores of mesoporous templates, distributing the templates containing the metal catalyst nanoparticles in a three-dimensional manner, and introducing a nanowire source into the pores of the templates to grow the nanowire source into nanowires along the length of the pores. Further provided are nanostructures produced by the method. The nanostructures have a uniform thickness. In addition, the nanostructures may have various shapes and can be controllably doped. The nanostructures can be applied to a variety of devices, including electronic devices, e.g., field effect transistors (FETs) and light-emitting diodes (LEDs), photodetectors, nano-analyzers, and high-sensitivity signal detectors for various applications, e.g., cancer diagnosis.

### BACKGROUND OF THE INVENTION

This non-provisional application claims priority under 35 U.S.C. § 119(a) on Korean Patent Application No. 10-2007-0025524 filed on Mar. 15, 2007, which is herein incorporated by reference.

1. Field of the Invention

Example embodiments relate to a method for producing nanostructures using mesoporous templates and nanostructures produced by the method. More specifically, example embodiments relate to a method for the mass production of nanostructures by introducing metal catalyst nanoparticles into a plurality of uniformly sized pores of mesoporous templates, distributing the templates containing the metal catalyst nanoparticles in a three-dimensional manner and introducing a nanowire source into the pores of the templates to grow the nanowire along the length of the pores, and nanostructures whose thickness is uniform, shape can be diversified and doping is controllable that are produced by the method.

2. Description of the Related Art

Nanowires are linear materials whose diameter is in the nanometer range (1 nm=10⁻⁹ m) and whose length is much larger than the diameter. Nanowires have a length of several hundred nanometers or on the order of micrometers (1 μm=10⁻⁵ m) or millimeters (1 mm=10⁻³ m). Nanowires exhibit various physical properties depending on their diameter and length.

Nanowires can be applied to a variety of microdevices due to their small size, and have advantages in the utilization of their inherent electron mobility characteristics along specific directions and optical properties such as polarization.

Semiconductor materials widely used in the semiconductor industry can be processed into the form of nanowires (i.e. semiconductor nanowires). Various types of semiconductor nanowires can be produced according to the intended purposes and their basic properties can be easily estimated. In addition, the physical and electrical properties of semiconductor nanowires can be manipulated by chemically modifying the surface of the nanowires. In consideration of these advantages, semiconductor nanowires will find many useful applications as basic materials for nanodevices.

Specifically, semiconductor nanowires can be applied to a variety of devices, including electronic devices, e.g., field effect transistors (FETs) and light-emitting diodes (LEDs), photodetectors, nano-analyzers, and high-sensitivity signal detectors for various applications, e.g., cancer diagnosis.

To attain uniform electrical and optical properties of nanowires, the thickness of the nanowires must be maintained at a constant level. FIGS. 1 and 2 show prior art methods for the production of nanowires. As shown in FIGS. 1 and 2, after metal nanoparticles are distributed on a two-dimensional planar substrate, a vapor-liquid-solid (VLS) mechanism (FIG. 1) or a solid-liquid-solid (SLS) mechanism (FIG. 2) is applied to the production of nanowires.

At this time, the metal nanoparticles must have a uniform size (i.e. monodispersed) in order to produce uniformly thick nanowires. However, it is practically very difficult to obtain monodispersed metal nanoparticles. Nanowires produced by the prior art methods have a thickness deviation of several nanometers (about several tens of %). In addition, the distribution of the metal nanoparticles on a two-dimensional substrate impedes the mass production of nanowires.

To overcome the problems of the prior art methods, some methods for the production of nanowires using templates have been introduced. As a material for such templates, anodic aluminum oxide (AAO) is mainly used. The size and length of pores formed within AAO templates are controlled in response to an applied voltage, which makes it difficult to form small-size pores at regular intervals in desired positions. Further, when the templates are incompletely etched in the lengthwise direction thereof to leave unetched end portions where pores are not formed, it is necessary to remove the unetched end portions, which renders the production of nanowires more complex. Moreover, since metal nanoparticles are distributed in a two-dimensional manner, the problems of the prior art methods shown in FIGS. 1 and 2 are encountered in the mass production of nanowires.

Most typical nanostructures have a relatively simple linear shape, such as cylindrical, hollow tubular or ribbon-like shape. Under such circumstances, there is a need to develop high-quality nanostructures having various shapes that can be used to fabricate a variety of devices, including solar cells and electroluminescent devices.

Most of the known production methods of nanowires are inappropriate for the mass production of uniformly thick nanowires and the production of nanostructures having various shapes. Thus, there is a need to develop a novel method for producing nanostructures.

### SUMMARY OF THE INVENTION

Example embodiments is intended to meet the above technical needs, and example embodiments provide a method for the mass production of nanowires by introducing metal catalyst nanoparticles into a plurality of pores of mesoporous templates having a constant diameter, distributing the resulting templates in a three-dimensional manner, and introducing a nanowire source into the pores of the templates to grow the nanowire source into nanowires having a uniform thickness.

Example embodiments provide a method for the mass production of nanostructures having various shapes using templates of various structures.

Example embodiments provide nanostructures with excellent characteristics that can be mass-produced by the method.

Example embodiments provide a method for the mass production of nanostructures, the method comprising the steps of:
(a) preparing mesoporous templates having a plurality of pores;
(b) introducing metal catalyst nanoparticles into the pores; and
(c) distributing the templates containing the metal catalyst nanoparticles in a three-dimensional manner and introducing a nanowire source into the pores to grow the nanowire source into nanowires.

In accordance with example embodiments, there are provided nanostructures whose thickness is uniform, shape can be diversified and doping is controllable that are produced by the method.

### BRIEF DESCRIPTION OF THE DRAWINGS

FIG. 1 is a schematic diagram illustrating a principle in which nanowires are produced by a vapor-liquid-solid (VLS) method.

FIG. 2 is a schematic diagram illustrating a principle in which nanowires are produced by a solid-liquid-solid (SLS) method.

FIG. 3 is a schematic diagram illustrating a principle in which nanostructures are produced in accordance with example embodiments.

FIG. 4 is a schematic diagram illustrating a principle in which nanostructures are produced in accordance with example embodiments.

FIG. 5 is a schematic diagram illustrating a principle in which mesoporous templates are prepared in accordance with example embodiments.

FIG. 6 is an exemplary diagram showing a two-dimensional distribution of templates on a substrate in accordance with the prior art and a three-dimensional distribution of mesoporous templates used to produce nanostructures in accordance with example embodiments.

FIG. 7a is a transmission electron microscope (TEM) image of mesoporous templates prepared in accordance with example embodiments, and FIG. 7b is an X-ray diffraction (XRD) pattern of mesoporous templates prepared in accordance with example embodiments.

FIG. 8a is a TEM image of mesoporous templates into which metal catalyst nanoparticles are introduced in accordance with example embodiments, and FIG. 8b is an XRD pattern of mesoporous templates into which metal catalyst nanoparticles are introduced in accordance with example embodiments.

FIG. 9a is a TEM image of mesoporous templates within which silicon nanowires are formed in accordance with example embodiments, and FIG. 9b is a TEM image of silicon nanowires separated from mesoporous templates in accordance with example embodiments.

FIG. 10 is an XRD pattern of mesoporous templates within which silicon nanowires are formed in accordance with example embodiments.

### DESCRIPTION OF THE PREFERRED EMBODIMENTS

Example embodiments will now be described in greater detail with reference to the accompanying drawings.

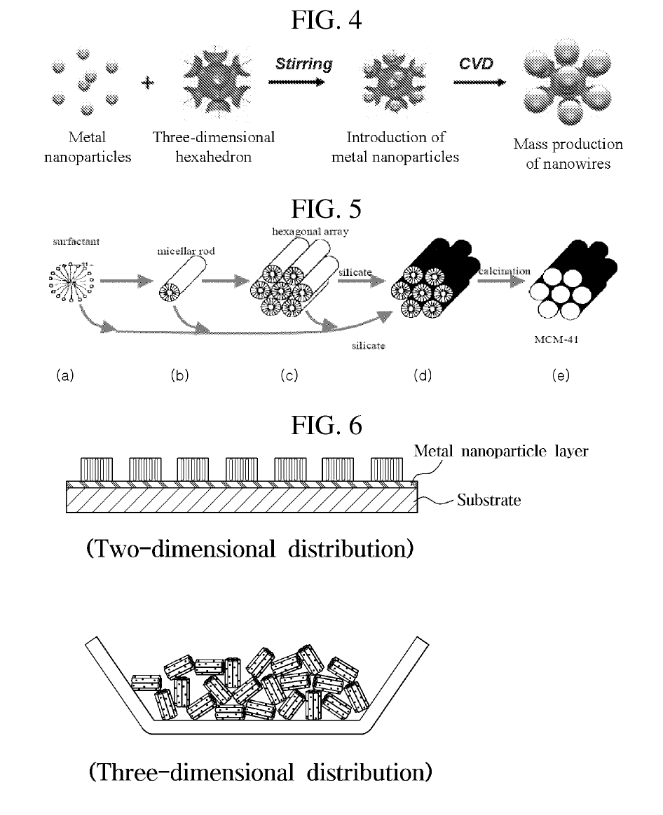

FIGS. 3 and 4 are schematic diagrams illustrating principles in which nanostructures are produced in accordance with example embodiments.

A method for producing nanostructures according to example embodiments shown in FIG. 3 is characterized in that templates having a plurality of uniform pores are used to grow nanowires with a uniform thickness. It is preferred that the templates be mesoporous and be made of a silicate.

Another characteristic of the method is that mesoporous templates in the form of a powder are distributed in a three-dimensional manner to achieve mass production of nanostructures. The nanostructures thus produced are preferably silicon nanostructures.

Another characteristic of the method is that mesoporous templates of various structures are used to mass-produce nanostructures of various shapes. The templates may have a two-dimensional hexagonal or three-dimensional hexahedral structure.

According to example embodiments, there is provided a method for producing nanostructures by preparing mesoporous templates (step (a)), introducing metal catalyst nanoparticles into pores of mesoporous templates (step (b)), and introducing a nanowire source into the pores to grow the nanowire using the metal catalyst nanoparticles (step (c)).

A more detailed explanation of the respective steps of the method according to example embodiments will be provided below.

(a) Preparation of Mesoporous Templates

FIG. 5 is a schematic diagram illustrating a principle in which templates used for the production of nanostructures are prepared in accordance with example embodiments.

First, a surfactant consisting of hydrophilic heads and hydrophobic tails, an acid for pH adjustment and the like are added to deionized water. The aqueous solution is stirred to allow the surfactant to be self-assembled. As a result, micelles are formed (FIG. 5a).

The aqueous solution is continuously stirred at room temperature for an appropriate time to allow the micelles to aggregate. As a result, micellar rods are formed (FIG. 5b). The micellar rods aggregate with the passage of time to form supramolecules in a hexagonal array (FIG. 5c).

The surfactant may be selected from the group consisting of poly(ethylene oxide)-poly(propylene oxide)-poly(ethylene oxide) (EOₘ-POₙ-EOₘ) copolymers. The use of EO₂₀-PO₇₀-EO₂₀ is preferred.

The aqueous solution preferably has a pH of from −1 to 3 and more preferably from 0 to 1.

A silicate as an inorganic material is added to the aqueous solution containing the supramolecules. The silicate solution is slowly stirred, followed by hydrothermal treatment in an autoclave. As a result, the hydrophilic heads of the surfactant located at the surface interact with the inorganic material to form template complexes (FIG. 5d).

The inorganic material can be selected from the group consisting of silicate compounds. Preferably, the inorganic material is tetraethylorthosilicate (TEOS).

Subsequently, the template complexes are separated from the aqueous solution by filtration, washed and calcined to remove the surfactant, leaving templates only (FIG. 5e).

The templates thus prepared have pores with a constant diameter. Accordingly, the use of the templates enables the production of nanowires having a uniform thickness.

On the other hand, mesoporous materials permitting fluid to flow therethrough are divided into microporous, mesoporous and macroporous materials by the size of pores formed therein. The microporous materials are defined as those having a pore size smaller than 2 nm, the mesoporous materials are defined as those having a pore size between 2 and 50 nm, and the macroporous materials are defined as those having a pore size larger than 50 nm. The templates used in accordance with example embodiments are preferably mesoporous.

The mesoporous templates have a large pore size sufficient to allow fluid to freely flow through the pores and a relatively large surface area sufficient to allow fluid to be in contact with the templates. The use of the mesoporous templates enables the production of nanostructures with excellent characteristics. At this time, the mesopores have a diameter deviation between −0.15 nm and +0.15 nm.

The pore size and structure of the templates in accordance with example embodiments can be freely varied. That is, the pore size of the mesoporous materials is varied by various factors, such as temperature and time, during the hydrothermal treatment. The pore size of almost all mesoporous materials is increased as the inner temperature of the autoclave increases and the retention time within the autoclave increases. The structure of the templates is largely determined by the kind of the polymer constituting the templates. Although the same kind of the polymer material is used, the structure of the templates may be varied depending on the molar ratio between the polymer and the inorganic material within the solution.

As explained above, the mesoporous templates can be processed into various structures. For example, the mesoporous templates may be hexagonal in cross section (FIG. 3) or have a hexahedral structure (FIG. 4). The use of the mesoporous templates enables the production of nanostructures having various shapes.

(b) Introduction of Metal Catalyst Nanoparticles into Pores of the Mesoporous Templates

First, a solution of a metal salt in deionized water and a solvent is prepared. Then, the mesoporous templates are added to the solution. The mixture is ultrasonicated at room temperature to form metal catalyst nanoparticles.

A change in the color of the aqueous solution can be observed to determine whether metal nanoparticles are formed. For example, when potassium tetrachloroaurate (III) (KAuCl₄) is used as the metal salt, the aqueous solution turns from yellow to purple in color.

Subsequently, the templates, within which the metal catalyst nanoparticles are formed, are separated from the aqueous solution by filtration, dried in an oven, and calcined to completely remove organic substances attached to the templates.

In the method of example embodiments, the metal salt may be selected from KAuCl₄ and HAuCl₄ is preferred.

Alternatively, introduction of metal catalyst nanoparticles into the pores of the mesoporous templates can be accomplished by refluxing aminopropyltriethoxysilane (APTES) having an amine group to functionalize the compound and mixing the functionalized compound with potassium tetrachloroaurate (III) (KAuCl₄). At this time, it is necessary to remove unwanted metal nanoparticles present outside the templates. It is preferred that a NaBH₄ solution as a reducing agent be added to reduce the unwanted metal nanoparticles.

(c) Formation of Nanowires within Pores of the Mesoporous Templates

The method of example embodiments is characterized in that silicon nanowires are grown by chemical vapor deposition (CVD) based on a vapor-liquid-solid (VLS) mechanism.

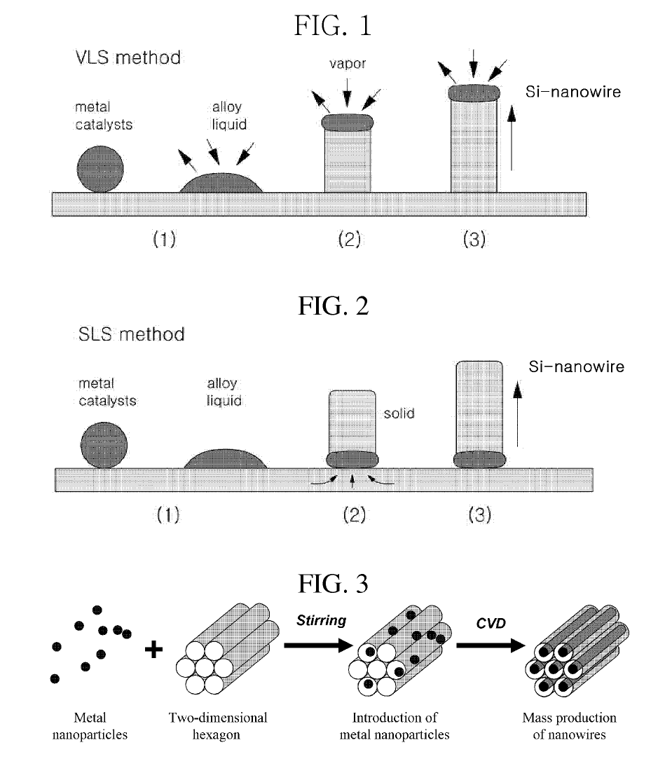

According to the vapor-liquid-solid method shown in FIG. 1, a vapor-phase silicon-containing species is condensed and crystallized on the surface of a molten catalyst, e.g., gold, cobalt or nickel, in a high-temperature furnace to be grown into silicon nanowires.

Specifically, the vapor-liquid-solid (VLS) method can be performed by placing the mesoporous templates in the form of a powder prepared in step (b) in a boat or crucible, putting the boat or crucible into a furnace, and heating the boat or crucible while feeding a gas and a nanowire source into the furnace to grow the nanowire source into nanowires.

The templates containing the metal catalyst nanoparticles are schematically shown in FIG. 6. The templates are distributed in a three-dimensional manner, which enables the mass production of nanowires. In contrast, according to the prior art, templates containing metal catalyst nanoparticles are distributed in a two-dimensional manner.

The gas used for the vapor-liquid-solid (VLS) method may be selected from the group consisting of Ar, N₂, He and H₂, but is not limited thereto. The flow rate of the gas is about 100 sccm and may vary depending on the type of processing.

The vapor-liquid-solid (VLS) method may be performed under a pressure lower than 760 torr and at a temperature of 370-600° C. The heating time may also be varied depending on the desired length of the nanostructures.

As for silicon nanowires, the nanowire source introduced for the vapor-liquid-solid (VLS) method may be SiH₄, SiCl₄, SiH₂Cl₂ or the like.

The silicon nanostructures may be doped with a dopant. By varying the kind and the composition of materials, the nanostructures may be formed to have a superlattice or hybrid composite structure.

The composite structure may be formed by combining the silicon nanostructure with a material selected from the group consisting of Group III-V compounds (e.g., gallium arsenide (GaAs) and gallium nitride (GaN)), carbon nanotubes (CNTs), zinc oxide (ZnO) and silicon carbide (SiC).

The templates can be removed when it is intended to use the nanostructures only. Selective removal of the templates can be accomplished in a chemical manner.

For example, the templates can be removed using an etchant such as a hydrofluoric (HF) solution.

Example embodiments are also directed to nanostructures whose thickness is uniform, shape can be diversified and doping is controllable that are produced by the method. The nanostructures of example embodiments exhibit excellent characteristics and may have various shapes. Therefore, the nanostructures of example embodiments can be applied to a variety of devices, including electronic devices, e.g., field effect transistors (FETs) and light-emitting diodes (LEDs), photodetectors, nano-analyzers, and high-sensitivity signal detectors for various applications, e.g., cancer diagnosis.

Hereinafter, Example embodiments will be explained in more detail with reference to the following examples. However, these examples are given for the purpose of illustration only and are not intended to limit example embodiments.

### EXAMPLES

### Example 1

### Production of Nanostructures

(a) Preparation of Mesoporous Templates

First, 4 g of EO₂₀-PO₇₀-EO₂₀ (P123) and 30 g of deionized water were added to 120 g of 2.0 M HCl. The solution was stirred at room temperature for 4 hours. After the solution was heated in a bath at 35° C., 8.5 g of tetraethylorthosilicate (TEOS) was slowly added thereto and stirred at 35° C. for 20 hours.

Subsequently, the resulting solution was subjected to hydrothermal treatment without stirring in an autoclave at 80° C. for 24 hours and filtered to obtain template complexes. An aqueous solution of ethanol and hydrochloric acid was mixed with the template complexes for 30 minutes to prepare a slurry. The slurry was filtered, washed with ethanol, and dried in an oven at 80° C. for 4 hours to separate templates from the aqueous solution.

Calcination was performed at 550° C. for 6 hours to completely remove organic substances attached to the templates.

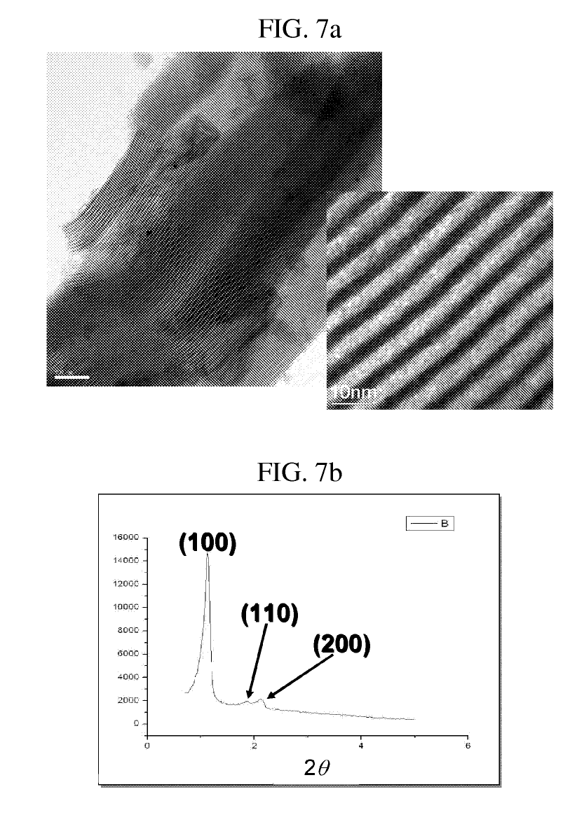

FIGS. 7a and 7b show a TEM image and an XRD pattern of the templates, respectively.

(b) Introduction of Metal Catalyst Nanoparticles within Pores of the Templates

First, 25 ml of a solution of 0.005 M potassium tetrachloroaurate (III) (KAuCl₄), 75 ml of deionized water and 100 ml of ethanol were mixed together. To the mixture were added the templates prepared in step (a). The mixture was ultrasonicated at room temperature for 3 hours to form metal nanoparticles.

Subsequently, the metal nanoparticles were separated from the mixture by filtration, washed with deionized water and ethanol, and dried in an oven at 100° C. for 4 hours

Calcination was performed at 500° C. for 6 hours to completely remove organic substances attached to the metal nanoparticles.

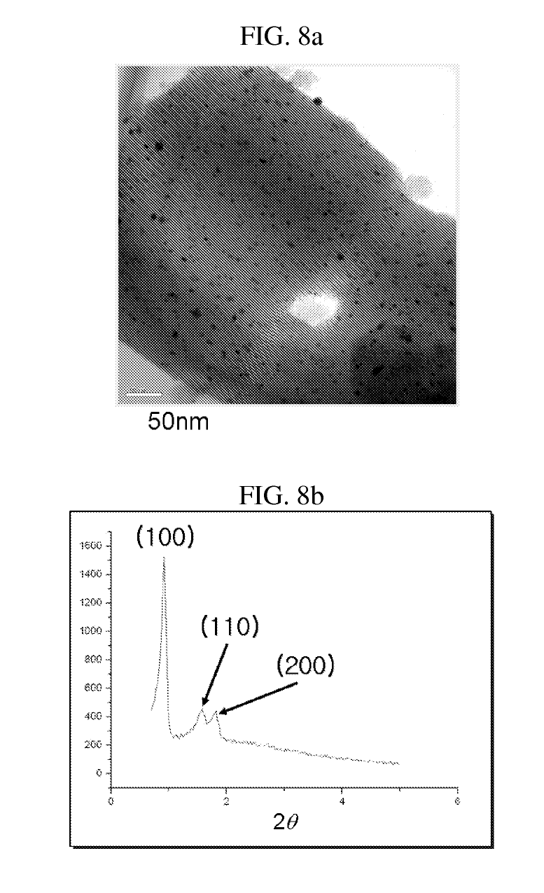

FIGS. 8a and 8b show a TEM image and an XRD pattern of the templates containing the metal nanoparticles, respectively.

(c) Formation of Nanostructures

0.05 mg of the templates in a powder form, into which the metal nanoparticles were introduced, were placed in a small-volume vial covered with quartz wool and put into a furnace. The templates were heated at a rate of 10-15° C./min. The processing pressure was maintained at 3 torr while feeding argon (Ar) and SiH₄ as a nanostructure source into the furnace at flow rates of 100 sccm and 20 sccm, respectively.

Silicon nanostructures were allowed to grow while maintaining a processing temperature of 460° C. for 30 minutes. The processing temperature was slowly lowered to room temperature to stop the growth of the nanostructures.

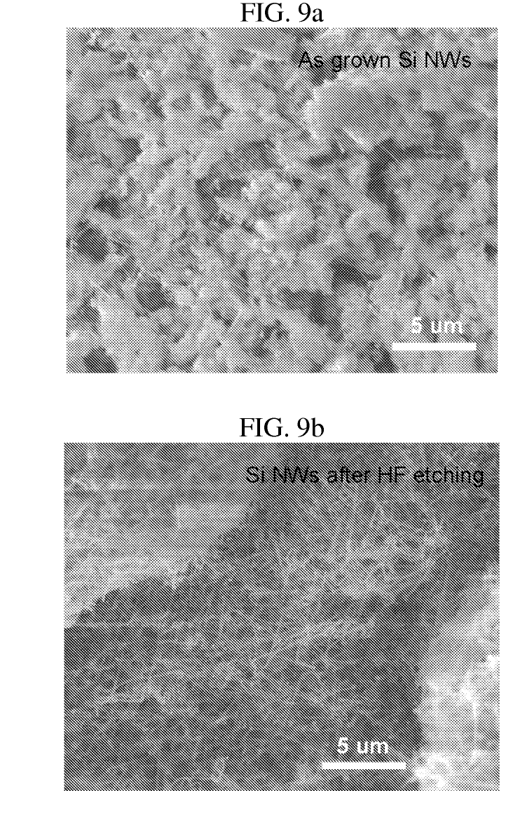

FIG. 9a is a TEM image of the templates within which the silicon nanostructures were grown and FIG. 9b is a TEM image of the silicon nanostructures separated from templates.

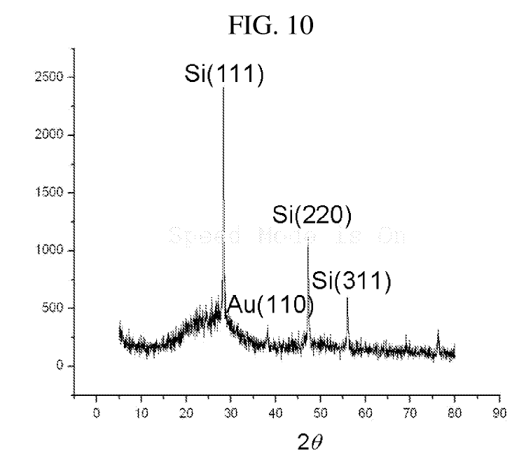

FIG. 10 is an XRD pattern of the templates within which silicon nanowires were grown.

Example embodiments have been described in detail with reference to the foregoing specific embodiments. However, Example embodiments are not limited to the embodiments. Those skilled in the art will appreciate that various modifications and variations are possible, without departing from the scope and spirit of the appended claims.

As apparent from the above description, according to the method of example embodiments, nanostructures having a uniform thickness can be mass-produced by introducing metal catalyst nanoparticles within a plurality of pores of mesoporous templates with a constant diameter, distributing the resulting templates in a three-dimensional manner, and introducing a nanowire source into the pores of the templates to grow the nanowire source into nanowires.

In addition, the pore size and shape of the mesoporous templates and the composition of materials can be varied to produce multi-functional nanostructures.

Nanostructures produced by the method of example embodiments can be used for the fabrication of a variety of electronic devices and photonic devices. In this case, the use of the nanostructures contributes to an improvement in the characteristics of electronic devices. The nanostructures can be applied to electronic devices for various applications.

1. A method for the mass production of nanostructures, the method comprising the steps of:
(a) preparing mesoporous templates having a plurality of pores;
(b) introducing metal catalyst nanoparticles into the pores; and
(c) distributing the templates containing the metal catalyst nanoparticles in a three-dimensional manner and introducing a nanowire source into the pores to grow the nanowire source into nanowires.

2. The method according to claim 1, wherein step (a) includes interacting a surfactant with an inorganic material in an aqueous solution to form template complexes.

3. The method according to claim 2, wherein the inorganic material is a silicate.

4. The method according to claim 2, wherein the surfactant is selected from the group consisting of poly(ethylene oxide)-poly(propylene oxide)-poly(ethylene oxide) (EOₘ-POₙ-EOₘ) copolymers.

5. The method according to claim 1, wherein the pores of the templates are mesopores having a diameter of 2 to 50 nm.

6. The method according to claim 1, wherein the pores of the templates have a diameter deviation between −0.15 nm and +0.15 nm.

7. The method according to claim 1, wherein the mesoporous templates have a two-dimensional hexagonal or three-dimensional hexahedral structure.

8. The method according to claim 1, wherein, in step (b), the metal catalyst nanoparticles are prepared by sonication of a solution of a metal salt in deionized water and a solvent.

9. The method according to claim 8, wherein the metal salt is selected from KAuCl₄ and HAuCl₄.

10. The method according to claim 8, wherein the solvent is ethanol.

11. The method according to claim 1, wherein, in step (b), the metal catalyst nanoparticles are introduced into the pores of the templates by sonication or using an amine group.

12. The method according to claim 1, wherein the nanowires are grown by chemical vapor deposition (CVD) based on a vapor-liquid-solid (VLS) mechanism.

13. The method according to claim 12, wherein the vapor-liquid-solid (VLS) method is performed by putting the templates into a furnace and heating the templates while feeding a gas and a nanowire source into the furnace to grow the nanowire source into nanowires.

14. The method according to claim 13, wherein the gas is selected from the group consisting of Ar, N₂, He and H₂.

15. The method according to claim 13, wherein the templates are heated under a pressure lower than 760 torr and at a temperature of 370-600° C.

16. The method according to claim 13, wherein the nanowire source is selected from the group consisting of SiH₄, SiCl₄ and SiH₂Cl₂.

17. The method according to claim 1, wherein, in step (c), the nanowires are doped with a dopant.

18. The method according to claim 1, further comprising the step of removing the templates after step (c).

19. A nanostructure produced by the method of claim 1.
